(19) United States
(12) Patent Application Publication
(10) Pub. No.: US 2026/0150560 A1
(43) Pub. Date: May 28, 2026

(54) DISPLAY DEVICE

(71) Applicant: LG Display Co., Ltd., Seoul (KR)

(72) Inventors: Hyun-Jik BAE, Paju-si (KR); Min-Ho LEE, Paju-si (KR)

(73) Assignee: LG Display Co., Ltd., Seoul (KR)

(21) Appl. No.: 19/195,096

(22) Filed: Apr. 30, 2025

(30) Foreign Application Priority Data
Nov. 28, 2024 (KR) 10-2024-0173786

(51) Int. Cl. H10K 59/80

(52) U.S. Cl. CPC H10K 59/879; H10K 59/8792

(57) ABSTRACT

A display device in some examples can include a substrate having a plurality of sub-pixels, and a light-emitting diode including a first light-emitting diode and a second light-emitting diode disposed in one of the plurality of the sub-pixels. The first light-emitting diode and the second light-emitting diode are configured to emit a same color light. The display device can further include a first optical member disposed in a first emission area of the first light-emitting diode, and a second optical member disposed in a second emission area of the second light-emitting diode, wherein a plurality of second optical members, including the second optical member, are arranged to overlap the second light emission area.

### CROSS-REFERENCE TO RELATED APPLICATION

This application claims priority under 35 U.S.C. § 119(a) to the Korean Patent Application No. 10-2024-0173786, filed in the Republic of Korea on Nov. 28, 2024, the entire contents of which are hereby expressly incorporated by reference into the present application.

### BACKGROUND

### Technical Field

The present disclosure relates to a display device, and more particularly to, a display device that can control viewing angles.

### Discussion of the Related Art

As technologies for display devices have advanced over the years, various display devices have been applied in various settings for various purposes in order to provide information to users. The display devices comprise not only electronic displays that simply transmit visual information in one direction, but also various electronic devices that require higher technology to receive user input and provide information with uses in response to confirmed user input.

For example, a display device can be included in a vehicle and provide various information to a driver and passengers of the vehicle. However, the display device of the vehicle needs to display contents appropriately to not interfere with an operations of the vehicle and avoid distracting the driver. For example, the display device needs to limit a display of content that can reduce a concentration of the driver while the vehicle is in operation.

### SUMMARY OF THE DISCLOSURE

Accordingly, one or more embodiments of the present disclosure are directed to a display device that substantially obviates one or more of the problems due to the limitations and disadvantages of the related art.

An aspect of the present disclosure is to provide a display device that can provide contents with a wide viewing angle in a first mode and with a narrow viewing angle in a second mode.

Another aspect of the present disclosure is to provide a display device that can have a beneficial visibility of a display image.

Another aspect of the present disclosure is to provide a display device that can improve a viewing angle when providing content at a narrow viewing angle by arranging plural optical members corresponding to each emission area emitting light in a second mode.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, the present disclosure provides a display device that includes a substrate comprising a plural sub-pixels, a light-emitting diode comprising a first light-emitting diode and a second light-emitting diode disposed in one of the sub-pixels, wherein the first light light-emitting diode and the second light-emitting diode emit a same color, a first optical member disposed in a first emission area of the first light-emitting diode, and a second optical member disposed in a second emission area of the second light-emitting diode, wherein a plurality of the second optical member are arranged corresponding to the second light emission area.

The first optical member can have a plane shape of a bar shape extending to a first direction and the second optical member has a plane shape of a circular or polygonal shape.

Each of the first emission area and the second emission area can have a plane shape of a bar shape extending to a first direction.

The display device can further include a first light-blocking layer disposed on the light-emitting diode.

A central axis of the second optical member and one edge of one of the first light-blocking layers can be positioned on a same straight line in a second direction that is a normal direction of a plane.

In one embodiment, the first light-blocking layer can include a metal layer.

For example, the first light-blocking layer can include a touch electrode.

The display device can further include an encapsulation member disposed between the light-emitting diode and the first light-blocking layer.

The display device can further include a second light-blocking layer disposed on the encapsulation member.

In one embodiment, the second light-blocking layer can include a black matrix.

The display device can further include a third light-blocking layer disposed between the encapsulation member and the second light-blocking layer.

In one embodiment, the third light-blocking layer can include a metal layer.

The second emitting diode can include a lower electrode, an emissive layer disposed on the lower electrode and an upper electrode disposed on the emissive layer.

The display device can further include a bank insulation layer disposed on the first electrode and having an opening corresponding to the second emission area.

In one embodiment, at least a portion of the first light-blocking layer can be arranged to overlap the bank insulation layer.

A separation distance in a first direction between the second optical members can be smaller than a length of the second emission area in the first direction.

In another aspect, the present disclosure provides a display device that includes a substrate comprising a plural sub-pixels, and an emission area comprising a first emission area and at least one second emission area disposed in one of the sub-pixels, wherein the first emission area and the second emission area emit a same color, wherein the first emission area emits light at a first viewing angle, wherein the second emission area emits light as a second viewing angle narrower than the first viewing angle, and wherein plural optical members are disposed corresponding to the second emission area.

The emission area can have plural second emission areas.

The first emission area can have a size larger than a size of the second emission area.

Each of the first emission area and the second emission area can have a plane shape of a bar shape extending to a first direction.

In one or more embodiments, the display device can provide content with a wide viewing angle in a first mode or with a narrow viewing angle in a second mode by using plural optical members with different shapes.

In the display device, as the size of the second emission area that emits light in the second mode increases, the display device can be driven at lower power in terms of power consumption reduction by improving the life time thereof.

The display device can improve the viewing angle required in the second mode by arranging plural second optical members corresponding to each second emission area emitting in the second mode.

It is to be understood that both the foregoing general description and the following detailed description are examples and explanatory, and are intended to provide further explanation of the inventive concepts as claimed.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates an example display device in accordance with one or more embodiments of the present disclosure.

FIG. 2 illustrates a functional block diagram of the display device in accordance with an embodiment of the present disclosure.

FIG. 3 illustrates a schematic circuit diagram of a pixel circuit included in the display device in FIG. 2.

FIG. 4 is an enlarged plane view illustrating arrangements of optical members included in the display device in accordance with an embodiment of the present disclosure.

FIG. 5 illustrates a schematic cross-sectional view of the display device taken along a line I-I′ in FIG. 4.

FIG. 6 illustrates a schematic cross-sectional view of the display device taken along a line II-II′ in FIG. 4.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the other component is directly on the other component or layer, or where there is another layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompasses all the meanings and coverages of the term “may” and vice versa.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

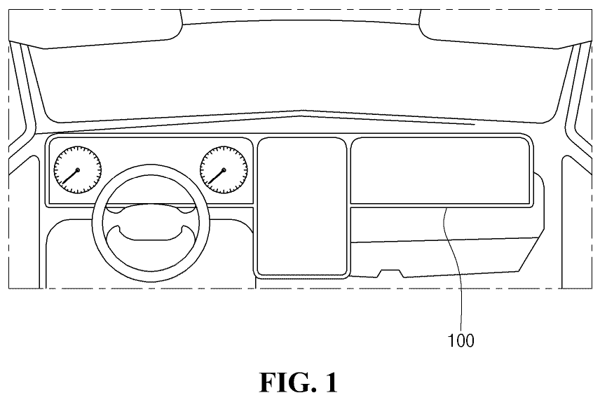

FIG. 1 illustrates an example display device in accordance with an embodiment of the present disclosure.

With reference to FIG. 1, a display device 100 can be arranged to at least a portion of a dashboard in a vehicle. The dashboard of the vehicle can comprise a configuration positioned in front of a front seat of the vehicle (e.g., driver's seat and/or passenger's seat). For example, the dashboard of the vehicle can have input configurations for operating various functions inside the vehicle (e.g., air conditioning, audio system, navigation system and the likes). But embodiments of the present disclosure are not limited thereto, and other functions, including self-driving, fuel or battery management, or maintenance can also be provided.

The display device 100 arranged on the dashboard of the vehicle can function as an input unit for operating at least a portion of various functions of the vehicle. The display device 10 can provide various information related to the vehicle, for example, vehicle operations information (e.g., current speed of the vehicle, remaining fuel or charge amount, driving distance and the likes), information on vehicle parts (e.g., damage to vehicle tires), and the likes. But embodiments of the present disclosure are not limited thereto.

The display device 100 can be positioned across the drivers' seat and the passenger's seat located in the front seat of the vehicle. Users of the display device 100 can comprise the driver of the vehicle and/or the passenger riding in the passenger's seat. Both the driver and the passenger of the vehicle can use the display device 100.

The display device 100 illustrated in FIG. 1 can only show a part thereof. The display device 100 illustrated in FIG. 1 can show only a display panel among various component included in the display device 100. For example, the display device 100 illustrated in FIG. 1 can show at least a part of a display area and a non-display area. Component of the display device 100 other than the parts illustrated in FIG. 1 can be mounted inside (or at least a part of) the vehicle.

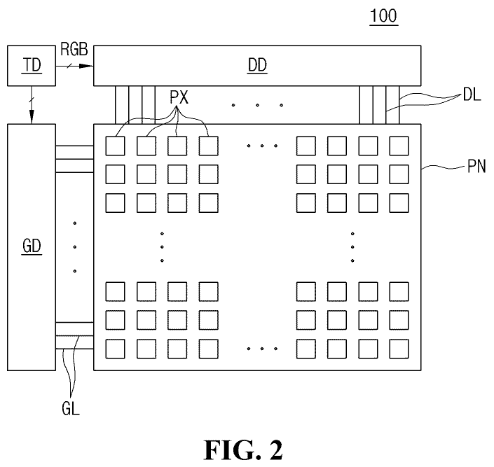

FIG. 2 illustrates a functional block diagram of the display device in accordance with an embodiment of the present disclosure.

The display device 100 in accordance with an embodiment of the present disclosure can comprise electroluminescent display device. The electroluminescent display device can comprise, but is not limited to, an organic light diode display device, a quantum-dot light emitting diode display device and/or an inorganic light emitting diode display device.

With reference to FIG. 2, the display device 100 can comprise a display panel PN, a data drive circuit or a data driver DD, a gate drive circuit of a gate driver GD and a timing controller TD.

The display panel PN can generate an image to be provided to a user. For example, the display panel PN can generate and display an image to be provided to a user through a plurality of pixels PXs each having a pixel circuit arranged therein.

The data drive circuit DD, the gate driver circuit GD and the timing controller TD can provide signals for operation of each pixel PX through signal lines. For example, the signal lines for proving signals for the operation of each pixel PX can comprise a plurality of data lines DLs and a plurality of gate lines GLs, among others.

The plurality of data lines DLs are arranged in a column direction and can comprise a plurality of lines connected to the pixel PX arranged in one column direction. The plurality of gate lines GLs are arranged in a row direction and can comprise a plurality of lines connected to the pixel PX arranged in one row direction.

Alternatively, the display device 100 can further comprise a power unit. In this case, a signal for the operation of the pixel PX can be provided through a power line connecting the power unit to the display panel PN. In one embodiment, the power unit can provide power to the data drive circuit DD and the gate drive circuit GD. The data drive circuit GD and the gate drive circuit GD can be driven based on the power provided from the power unit.

For example, the data drive circuit DD can apply a data signal to each pixel PX through a plurality of data lines DLs, the gate drive circuit GD can apply a gate signal to each pixel PX through a plurality of gate lines GLs, and the power unit can supply a power voltage to each pixel PX through a power voltage supply line.

The timing controller TD can control the data drive circuit DD and the gate drive circuit GD. For example, the timing controller TD can rearrange digital video data input from the outside to match the resolution of the display panel PN and supply it to the data drive circuit DD.

The data drive circuit DD can convert digital video data RGB input from the timing controller TD into analog data voltage based on a data control signal and supply it to the plural data lines DLs.

The gate drive circuit GD can generate scan signals and emission signals based on gate control signals. For example, the gate drive circuit GD can comprise a scan driver and an emission signal driver. The scan driver generate a scan signal in a row-sequential manner and supply into scan lines to drive at least one scan line connected to each pixel row. The emission signal driver can generate an emission signal in a row-sequential manner and supply it to the emission signal lines to drive at least one emission signal line connected to each pixel row.

In one embodiment, the gate drive circuit GD can be arranged on the display panel PN in a GIP (Gate-driver In Panel) manner. For example, the gate drive circuit GP can be divided into a plurality of pieces and arranged on at least two sides of the display panel PN, respectively. The display panel PN can comprise a display area and a non-display area surrounding the display area.

The display area in the display panel PN can include a plurality of pixels PXs arranged in a row direction and a column direction. For example, each of the pixels PXs can be arranged in an area where a plurality of data lines DLs and a plurality of gate lines GL cross.

One pixel PX can comprise a plurality of sub-pixels emitting different colors from each other. For example, a pixel PX can use three sub-pixels to implement blue, red and green, but is not limited thereto. In another embodiment, the pixel PX can further comprise sub-pixels to implement a specific color, for example, white. But embodiments of the present disclosure are not limited thereto, but other colors can be used, including magenta and/or yellow-green.

In the pixel PX, an area implementing blue can be referred to as a blue sub-pixel, an area implementing red can be referred to as a red sub-pixel, and an area implementing green can be referred to as a green sub-pixel.

Each of the sub-pixels can comprise a light-emitting diode. The light-emitting diode can comprise a first light-emitting diode and a second light-emitting diode each of which emits a same color.

Each of the sub-pixels can comprise an optical member. The optical member can comprise a first optical member that reflects light from the first light-emitting diode in a specific direction and a second optical member that reflect light form the second light-emitting diode in a specific direction. For example, each of the first optical member and the second optical member can be implemented as a lens, but is not limited thereto.

In one embodiment, the first optical member can be arranged in an optical area that provides light to a first range to form a first viewing angle, and the second optical member can be arranged in an optical area that provides light to a second range to form a second viewing angle. For example, the first range can correspond to a wider range than the second range. Accordingly, the first optical member and the second member can limit the viewing angle of each of the plurality of sub-pixels.

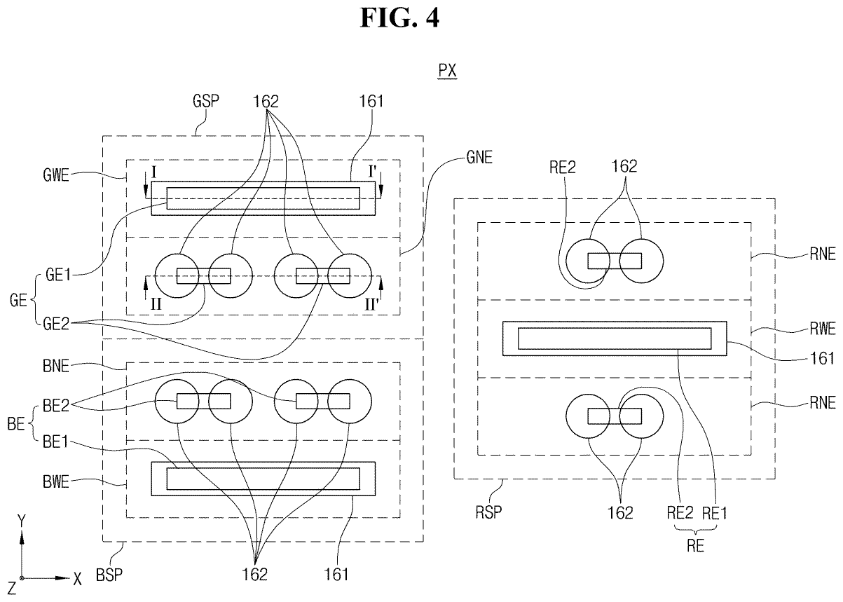

The first optical member and the second optical member will be described in more detail with reference to FIGS. 4 to 6.

The non-display area can be arranged along a periphery of the display area. Various components for the operation of the pixel circuits arranged in the pixel PX can be arranged in the non-display area. For example, at least a part of the gate drive circuit GD can be arranged in the non-display area. The non-display area can be referred to as a bezel area.

When the display panel PN is used in the vehicle illustrated in FIG. 1, the field of view of at least some areas on the display panel PN may need to be restricted pursuant to the user's request. For example, in case an image displayed in an area that provides entertainment function and seat information for a passenger sitting in the front passenger's seat among the display area of the display panel PN, it can be necessary to restrict the field of view of the image displayed in that area under the user's request because the image can interfere with driving.

Accordingly, each pixel PX included in the display panel PN can be driven (or operated) in a first mode or a second mode depending on the driving mode. For example, when the pixel PX is driven in the first mode, the first light-emitting diode included in the pixel PX emits light based on a selection signal, and light from the first light-emitting diode is provided to the first range through the first optical member to form a first viewing angle, for example, a wide viewing angle. In addition, when the pixel PX is driven in the second mode, the second light-emitting diode included in the pixel PX emits light based on a selection signal, and light from the second light-emitting diode is provided to the second range through the second optical member to form a second viewing angle, for example, a narrow viewing angel. The first mode can correspond to a mode in which the corresponding pixel PX is controlled in a wide viewing angle (Share mode), and the second mode can correspond to a mode in which the corresponding pixel PX is driven in a narrow viewing angle (Private Mode).

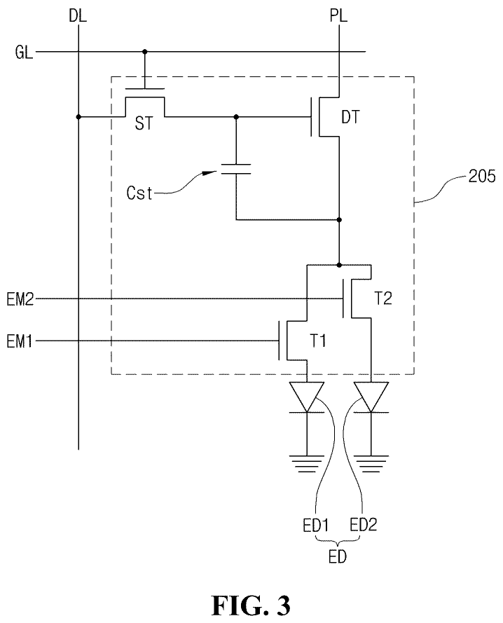

FIG. 3 illustrates a schematic circuit diagram of a pixel circuit included in the display device in FIG. 2. The pixel circuit illustrated in FIG. 3 indicates one embodiment of a pixel circuit corresponding to each of the plural sub-pixels of the plural pixels PXs included in the display device 100 described with reference to FIG. 2.

As illustrated in FIG. 3, the pixel circuit can comprise a plurality of transistors DT, ST, T1 and T2, a capacitor Cst and a light-emitting diode ED. The light-emitting diode ED can comprise a first light-emitting diode ED1 and a second light-emitting diode ED2.

A driving transistor DT can control a driving current applied to the plural light-emitting diodes ED1 and ED2 depending on a source-gate voltage. The driving transistor DT and the capacitor Cst can be connected to a switching transistor ST. A first electrode of the driving transistor DT can be connected to a power supply line PL.

The switching transistor ST can be connected to the gate line GL and can be supplied with a gate signal. The switching transistor ST can be turned on or off by the gate signal. A first electrode of the switching transistor ST can be connected to the data line DL. In this case, the data signal can be supplied to a gate electrode of the driving transistor DT through the switching transistor ST in response to the switching transistor ST being turned on.

The capacitor Cst can be arranged between the gate electrode and the second electrode of the driving transistor DT. The capacitor Cst can maintain a signal applied to the gate electrode of the driving transistor DT for one or more frames.

In some embodiment, the driving transistor DT, the switching transistor ST and the capacitor Cst can be referred to as a driving part 205 as components for driving light emission of the light-emitting diode (e.g., first light-emitting diode ED1 and second light-emitting diode ED2). However, the present disclosure is not limited to those terms.

The first light-emitting diode ED1 can be connected to a first transistor T1 that can be turned on or off by a first emission signal EM1. The second light-emitting diode ED2 can be connected to a second transistor T2 that can be turned on or off by a second emission signal EM2. The driving part 205 of the pixel circuit further comprises the first and second transistors T1 and T2.

In this case, the first light-emitting diode ED1 or the second light-emitting diode ED2 can be connected to other component of the pixel circuit, for example, the driving transistor DT depending on the modes. The modes can be specified by a user's input or determined when a pre-specified condition is satisfied. For example, when a pre-specified first condition is satisfied, the first light-emitting diode ED1 can emit light based on the supply of the first emission signal EM1. When a pre-specified second condition is satisfied, the second light-emitting diode ED2 can emit light based on the supply of the second emission signal. The first condition can comprise a pre-specified condition for the driving of the first mode. The second condition can comprise a pre-specified condition for the driving of the second mode.

The plurality of the transistors of FIG. 3 can comprise at least one of amorphous silicon, polycrystalline silicon and oxide semiconductor such as IGZO. The first electrode of the second electrode of the transistors can be a source electrode or a drain electrode. For example, the first electrode can be a source electrode and the second electrode can be a drain electrode. Alternatively, the first electrode can be a drain electrode and the second electrode can be a source electrode. But embodiments of the present disclosure are not limited thereto.

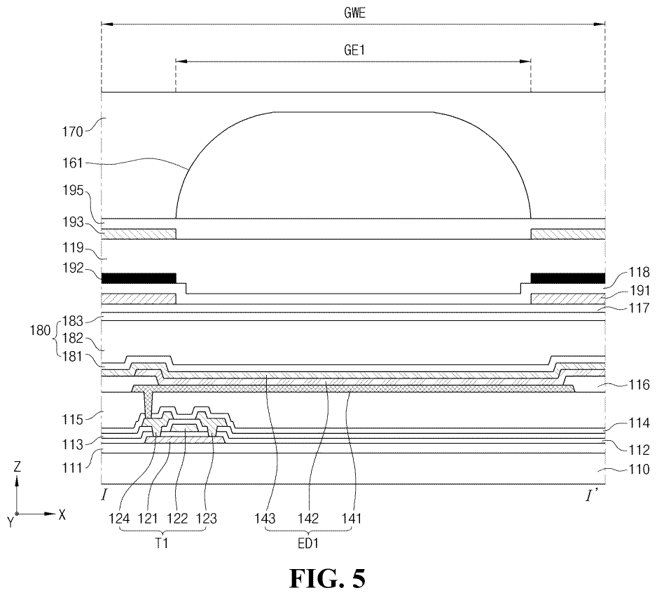

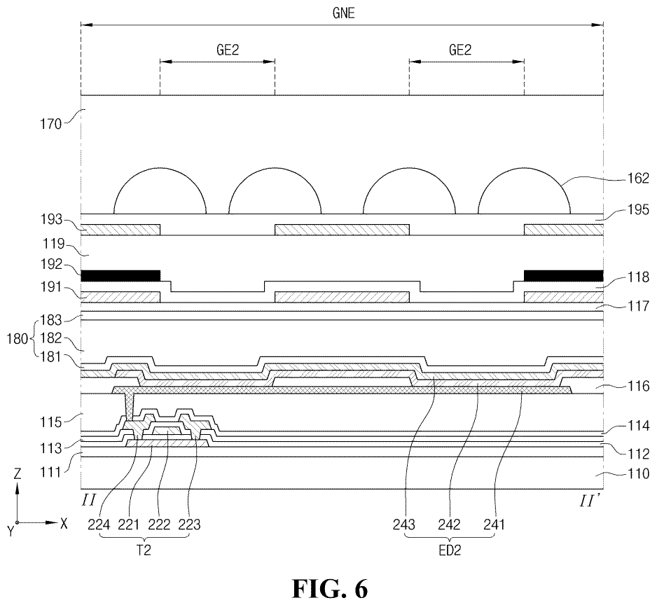

FIG. 4 is an enlarged plane view illustrating arrangements of optical members included in the display device in accordance with an embodiment of the present disclosure. FIG. 5 illustrates a schematic cross-sectional view of the display device taken along a line I-I′ in FIG. 4. FIG. 6 illustrates a schematic cross-sectional view of the display device taken along a line II-II′ in FIG. 4.

In FIG. 4, the plane view of the pixel PX that comprises three sub-pixels, for example, a first sub-pixel RSP, a second sub-pixel GSP and a third sub-pixel BSP are illustrated. In FIG. 5, a pixel where a first optical member 161 is arranged is illustrated as an embodiment of the display device 100 taken along a line I-I′ of FIG. 4. In FIG. 6, a pixel where a second optical member 162 is arranged is illustrated as an embodiment of the display device 100 taken along a line II-II′ of FIG. 4.

In addition, for convenience of explanation, in FIGS. 5 and 6, only areas corresponding to a first optical area GWE and a second optical area GNE of the second sub-pixel GSP among three sub-pixels RSP, GSP and BSP illustrated in FIG. 4 are illustrated, but other sub-pixels RSP and BSP can be formed with the same configuration.

Hereinafter, for convenience of explanation, the horizontal direction on the plane is illustrated as a first direction (X direction) and the vertical direction the plane is illustrated as a second direction (Y direction). In addition, the normal direction of the plane defined by the first direction (X) and the second direction (Y), for example, the thickness direction of the display device 100 can be defined as a third direction (Z direction).

With reference to FIG. 4, the pixel PX can comprise a plurality of sub-pixels RSP, GSP and BSP emitting different colors from each other. For example, the pixel PX can comprise a first sub-pixel RSP implementing a red color, a second sub-pixel GSP implementing a green color and a third sub-pixel BSP implementing a blue color. But embodiments of the present disclosure are not limited thereto. In some embodiments, each of the first sub-pixel RSP, the second sub-pixel GSP and the third sub-pixel BSP can be referred to as a red sub-pixel, a green sub-pixel and a blue-subpixel, respectively. The pixel circuit illustrated in FIG. 3 can be arranged in each of the sub-pixels RSP, GSP and BSP include in the pixel PX.

Each of the sub-pixels RSP, GSP and BSP can comprise a first optical area RWE, GWE or BWE and a second optical area RNE, GNE or BNE each of which supplies different viewing angles.

The first optical area RWE, GWE or BWE in each sub-pixel RSP, GSP or BSP can be operated individually from the second optical area RNE, GNE or BNE in the corresponding sub-pixel. For example, each sub-pixel RSP, GSP or BSP can comprise a first light-emitting diode ED1 (FIG. 5) arranged in a first optical area RWE, GWE or BWE in the corresponding sub-pixel RSP, GSP or BSP, and a second light-emitting diode ED2 (FIG. 6) arranged in a second optical area RNE, GNE or BNE in the corresponding sub-pixel RSP, GSP or BSP.

In one pixel PX, both the first light-emitting diode ED1 and the second light-emitting diode ED2 can be respectively arranged in the first optical area RWE, GWE or BWE and the second optical area RNE, GNE or BNE of the sub-pixels RSP, GSP or BSP.

With reference to FIGS. 4 to 6, each of the light-emitting diodes ED1 and ED2 can have an emission area RE, GE or Be. The first light-emitting diode ED1 arranged in a first optical area RWE, GWE or BWE of each sub-pixel RSP, GSP or BSP can have a first emission area RE1, GE1 or BE1. The second light-emitting diode ED2 arranged in a second optical area RNE, GNE or BNE of each sub-pixel RSP, GSP or BSP can have at least two emission areas RE2, NE2 or BE2.

With reference to FIG. 4, at least one first optical member 161 can be arranged to overlap with the first emission area RE1, GE1 or BE1 of the first light-emitting diode ED1 in the first optical area RWE, GWE or BWE of each sub-pixel RSP, GSP or BSP. At least two second optical members 162 can be arranged to overlap with one second emission area RE2, GE2 or BE2 of the second light-emitting diode ED2 in the second optical area RNE, GNE or BNE of each sub-pixel RSP, GSP or BSP. The first optical area RWE, GWE or BWE can have a first viewing angle, and the second optical area RNE, GNE or BNE can have a second viewing angle smaller than the first viewing angle.

With reference to FIGS. 4 to 6, the display device 100 in accordance with some embodiments can comprise a substrate 110, a buffer layer 111, a gate insulation layer 112, a interlayer insulation layer 113, a lower passivation layer 114, an overcoat layer 115, a bank insulation layer 116, a first transistor T1, a second transistor T2, a first light-emitting diode ED1, a second light-emitting diode ED2, an encapsulation member 180, a first insulation layer 117, a first light-blocking layer 191, a second upper insulation layer 118, a second light-blocking layer 192, a planarization layer 119, a third light-blocking layer 193, a third upper insulation layer 195, a first optical member 161, a second optical member 162 and an optical member passivation layer 170.

The substrate 110 can comprise an insulating material. The substrate 110 can comprise a transparent material. For example, the substrate can comprise glass or plastics. But other materials can be used, such as quartz or transparent conductive oxides.

The buffer layer 111 can be disposed on the substrate 110. The buffer layer 111 can comprise an insulating material. For example, the buffer layer 111 can comprise, but is not limited to, an inorganic insulating material such as silicon oxide (SiOₓ, wherein 0<x≤2) and silicon nitride (SiNₓ, wherein 0<x≤2). The buffer layer 111 can have a multiple-layer structure. For example, the buffer layer 111 can have a lamination structure of a layer of silicon nitride (SiNₓ) and a layer of silicon oxide (SiOₓ). But embodiments of the present disclosure are not limited thereto.

The buffer layer 111 can be positioned between the substrate 110 and the driving part 205 of each sub-pixel RSP, GSP or BSP and can prevent or reduce contamination owing to the substrate 110 in the course of forming the driving part 205. For example, the upper surface of the substrate 110 toward the driving part of each sub-pixel RSP, GSP or BSP can be covered with the buffer layer 111. The driving part 205 of each sub-pixel RSP, GSP or BSP can be positioned on the buffer layer 111.

The gate insulation layer 112 can be disposed on the buffer layer 111. The gate insulation layer 112 can comprise an insulating material. For example, the gate insulation layer 112 can comprise an inorganic insulating material such as silicon oxide (SiOₓ, wherein 0<x≤2) and silicon nitride (SiNₓ, wherein 0<x≤2). The gate insulation layer 112 can comprise a material having a high dielectric constant. For example, the gate insulation layer 112 can comprise High-K material such as hafnium oxide (HfO). The gate insulation layer 112 can have a multiple-layer structure. But embodiments of the present disclosure are not limited thereto.

The gate insulation layer 112 can be extended between the semiconductor layer 121 or 221 of the transistor T1 or T2, and the gate electrode 122 or 222. For example, the gate electrode 122 or 222 of the first transistor T1 or the second transistor T2 can be insulated from the semiconductor layer 121 or 221 of the first transistor T1 or the second transistor T2 by the gate insulation layer 112. The gate insulation layer 112 can cover the semiconductor layer 121 or 221 of each sup-pixel RSP, GSP or BSP, respectively. The gate electrode 122 or 222 of the first transistor T1 or the second transistor T2 can be located on the gate insulation layer 112.

The interlayer insulation layer 113 can be disposed on the gate insulation layer 112. For example, the interlayer insulation layer 113 can comprise, but is not limited to, an inorganic insulating material such as silicon oxide (SiOₓ, wherein 0<x≤2) and silicon nitride (SiNₓ, wherein 0<x≤2). The interlayer insulation layer 113 can be extended between each gate electrode 122 or 222 of the transistors T1 and T2 and the source electrode 123 or 223, and between the gate electrode 122 or 222 and the drain electrode 124 or 224. For example, each of the source electrode 123 or 223 and the drain electrode 124 or 224 of the first transistor T1 and the second transistor T2 can be insulated from the gate electrode 122 or 222 by the interlayer insulation layer 113. The interlayer insulation layer 113 can cover the gate electrode 122 or 222 of the first transistor T1 and the second transistor T2, respectively. Each of the source electrodes 123 and 223 and the drain electrodes 124 and 224 of each sub-pixel RSP, GSP or BSP can be located on the interlayer insulation layer 113. The gate insulation layer 112 and the interlayer insulation layer 113 can expose a source area and a drain area of the semiconductor layer 121 or 221 arranged in each sub-pixel RSP, GSP or BSP.

The lower passivation layer 114 can be disposed on the interlayer insulation layer 113. The lower passivation layer 114 can comprise an insulating material. For example, the lower passivation layer can comprise, but is not limited to, an inorganic insulating material such as silicon oxide (SiOₓ, wherein 0<x≤2) and silicon nitride (SiNₓ, wherein 0<x≤2). But embodiments of the present disclosure are not limited thereto.

The lower passivation layer 114 can prevent damages to the driving part 205 due to external moisture and/or shocks. The lower passivation layer 114 can be extended along an upper surface of the first transistor T1 or the second transistor T2. The lower passivation layer 114 can contact the interlayer insulation layer 113 in the outside of the driving part 205 disposed in each sub-pixel RSP, GSP or BSP.

The overcoat layer 115 can be disposed on the lower passivation layer 114. The overcoat layer 115 can comprise an insulating material. The overcoat layer 115 can comprise a material different from the material of the lower passivation layer 114. For example, the overcoat layer 114 can comprise an organic insulating material.

The overcoat layer 115 can eliminate the step caused by the driving part 205 of each sub-pixel RSP, GSP or BSP. For example, the overcoat layer 115 facing the substrate 110 can have a flat upper surface.

The first transistor T1 and the second transistor T2 can be arranged on the substrate 110. The first transistor T1 can be electrically connected between a drain electrode of the driving transistor DT and a first lower electrode 141 of the first light-emitting diode ED1. The second transistor T2 can be electrically connected between a drain electrode of the driving transistor DT and a second lower electrode 241 of the second light-emitting diode ED2.

The first transistor T1 can have the same structure as the structure of the switching transistor ST and the driving transistor DT.

The first transistor T1 can comprise the first semiconductor layer 121, the first gate electrode 122, the first source electrode 123 and the first drain electrode 124.

For example, the first semiconductor layer 121 can be disposed between the buffer layer 111 and the gate insulation layer 112, and the first gate electrode 122 can be disposed between the gate insulation layer 112 and the interlayer insulation layer 113. Both the first source electrode 123 and the first drain electrode 124 can be disposed between the interlayer insulation layer 113 and the lower passivation layer 114. The first gate electrode 122 can overlap with a channel region of the first semiconductor layer 121. The first source electrode 123 can be electrically connected to a source region of the first semiconductor layer 121. The first drain electrode 124 can be electrically connected to a drain region of the first semiconductor layer 121.

The second transistor T2 can comprise the second semiconductor layer 221, the second gate electrode 222, the second source electrode 223 and the second drain electrode 224. For example, the second semiconductor layer 221 can be positioned in the same layer as the first semiconductor layer 121, the second gate electrode 222 can be positioned in the same layer as the first gate electrode 122, and the second source electrode 223 and the second drain electrode 224 can be positioned in the same layer as the first source electrode 123 and the first drain electrode 124, respectively. But embodiments of the present disclosure are not limited thereto.

Each of the first light-emitting diode ED1 and the second light-emitting diode ED2 in each sup-pixel RSP, GSP or BSP can be disposed on the overcoat layer 115 of the corresponding sub-pixel RSP, GSP or BSP. For example, the first lower electrode 141 of the first light-emitting diode ED1 can be electrically connected to the first drain electrode 124 or the first source electrode 123 of the first transistor T1 through a contact hole penetrating the lower passivation layer 114 and the overcoat layer 115. The second lower electrode 241 of the second light-emitting diode ED2 can be electrically connected to the second drain electrode 224 or the second source electrode 223 of the second transistor T1 through a contact hole penetrating the lower passivation layer 114 and the overcoat layer 115. But embodiments of the present disclosure are not limited thereto.

The first light-emitting diode ED1 can emit light of a specific color. For example, the first light-emitting diode ED1 can comprise a first lower electrode 141, a first emissive layer 142 and a first upper electrode 143 laminated sequentially on the substrate 110. But embodiments of the present disclosure are not limited thereto, and a different order can be used.

The first lower electrode 141 can comprise a conductive material. The first lower electrode 141 can comprise a material with high reflectivity. In one embodiment, the first lower electrode 141 can comprise a metal such as aluminum (Al) and/or silver (Ag). The first lower electrode 141 can have a multiple-layer structure. For example, the first lower electrode 141 can have a structure where a reflective electrode made of metal is positioned between transparent electrodes made of a transparent conductive material such as ITO and/or IZO. But embodiments of the present disclosure are not limited thereto, and other transparent and conductive material can be used.

The first emissive layer 142 can generate light with luminance or brightness corresponding to the voltage difference between the first lower electrode 141 and the first upper electrode 143. For example, the first emissive layer 142 can comprise an emitting material layer (EML) including an emission material. The emission material can comprise an organic material, an inorganic material and/or a hybrid material.

The first emissive layer 142 can have a multiple-layer structure. For example, the first emissive layer 142 can further comprise at least one of a hole injection layer (HIL), a hole transport layer (HTL), an electron transport layer (ETL) and an electron injection layer (EIL). But embodiments of the present disclosure are not limited thereto. For example, various blocking layers can also be used.

The first upper electrode 143 can comprise a conductive material. The first upper electrode 143 can comprise a material other than the material of the first lower electrode 141. For example, the first upper electrode 143 can be a transparent electrode with a transparent conductive material such as ITO and/or IZO. In this case, the light generated in the first emissive layer 142 can be emitted through the first upper electrode 143 in the display device 100.

The second light-emitting diode ED2 can implement an emission of the same color light as the first light-emitting diode ED1 arranged in the same sub-pixel RSP, GSP or BSP. For example, the second light-emitting diode ED2 can comprise a second lower electrode 241, a second emissive layer 242 and a second upper electrode 243 laminated sequentially on the substrate 110.

Each of the second lower electrode 241, the second emissive layer 242 and the second upper electrode 243 can be corresponded to the first lower electrode 141, the first emissive layer 142 and the first upper electrode 143, respectively. For example, the second lower electrode 241 can be arranged with respect to the second light-emitting diode ED2 as the first lower electrode 141, and the same applies to the second emissive layer 242 and the second upper electrode 243. For example, the first light-emitting diode ED1 and the second light-emitting diode ED2 can be arranged with the same structure, but is not limited thereto. In another embodiment, at least a part of the configuration of the first light-emitting diode ED1 and the second light-emitting diode ED2 can be arranged differently.

The second emissive layer 242 can be spaced apart from the first emissive layer 142. In this case, light emission due to leakage current can be prevented or reduced in the display device 100 in accordance with an embodiment of the present disclosure.

In some embodiments, the display device 100 can generate light in only one of the first emissive layer 142 and the second emissive layer 242 depending on a user's selection or a pre-specified condition.

The second lower electrode 241 in each sub-pixel RSP, GSP or BSP can be spaced apart from the first lower electrode 141 in the corresponding sub-pixel RSP, GSP or BSP. For example, a bank insulation layer 116 can be arranged between the first lower electrode 141 and the second lower electrode 241 in each sub-pixel RSP, GSP or BSP. The bank insulation layer 116 can comprise an insulating material. For example, the bank insulation layer 116 can comprise an organic insulating material. The bank insulation layer 116 can comprise a material different from the material of the overcoat layer 115.

The second lower electrode 241 in each sub-pixel RSP, GSP or BSP can be insulated from the first lower electrode 141 in the corresponding sub-pixel RSP, GSP or BSP by the bank insulation layer 116. For example, the bank insulation layer 116 can cover an edge of the first lower electrode 141 and an edge of the second lower electrode 241 can be disposed within each sub-pixel RSP, GSP or BSP.

The bank insulation layer 116 can distinguish the first emission area RE1, GE1 or BE1 of the first light-emitting diode ED1 and the second emission area RE2, GE2 or BE2 of the second light-emitting diode ED2. For example, the first emission area RE1, GE1 or BE1 of the first light-emitting diode ED1 can be defined as an area on the first lower electrode 141 exposed by the bank insulation layer 116.

The bank insulation layer 116 can be arranged to have at least two openings on the second lower electrode 241. For example, the bank insulation layer 116 can cover an edge of the second lower electrode 241 and a central area spaced apart from the edge of the second lower electrode 241. Since the bank insulation layer 116 has at least two openings on the second lower electrode 241, the second light-emitting diode ED2 can have at least two second emission areas RE2, GE2 and BE2. With reference to FIG. 4, the size or dimension of the first emission area RE1, GE1 or BE1 of the first light-emitting diode ED1, which is separated from the second-light-emitting diode ED2 within each sub-pixel RSP, GSP or BSP, can be larger than the size or dimension of the second emission area RE2, GE2 or BE2, but is not limited thereto.

The first emissive layer 142 and the first upper electrode 143 of the first light-emitting diode ED1 arranged in each sub-pixel RSP, GSP or BSP can be laminated on at least a portion of the corresponding first lower electrode 141 exposed by the bank insulation layer 116. More particularly, the first emissive layer 142 and the first upper electrode 143 can be laminated on a portion of the first lower electrode 141 exposed by the bank insulation layer 116 and the bank insulation layer 116.

The second emissive layer 242 and the second upper electrode 243 of the second light-emitting diode ED2 arranged in each sub-pixel RSP, GSP or BSP can be laminated on at least a portion of the corresponding second lower electrode 241 exposed by the bank insulation layer 116. More particularly, the second emissive layer 242 and the second upper electrode 243 can be laminated on a portion of the second lower electrode 241 exposed by the bank insulation layer 116 and the bank insulation layer 116.

The second upper electrode 243 in each sub-pixel RSP, GSP or BSP can be electrically connected to the second upper electrode 243 in the corresponding sub-pixel RSP, GSP or BSP. For example, voltages applied to the second upper electrode 243 of the second light-emitting diode ED2 located in each sub-pixel RSP, GSP or BSP can be the same as voltages applied to the first upper electrode 143 of the first light-emitting diode ED1 located in the corresponding sub-pixel RSP, GSP or BSP. The second upper electrode 243 in each sub-pixel RSP, GSP or BSP can comprise a material as the material of the first upper electrode 143 in the corresponding sub-pixel RSP, GSP or BSP. For example, the second upper electrode 243 in each sub-pixel RSP, GSP or BSP can be formed simultaneously with the first upper electrode 143 in the corresponding sub-pixel RSP, GSP or BSP. The second upper electrode 243 in each sub-pixel RSP, GSP or BSP can be extended onto the bank insulation layer 116 and can contact directly the first upper electrode 143 in the corresponding sub-pixel RSP, GSP or BSP. The luminance or brightness of the first optical area RWE, GWE or BWE and the luminance or brightness of the second optical area RNE, GNE or BWE located within each sub-pixel RSP, GSP or BSP can be controlled by the driving current generated in the corresponding sub-pixel RSP, GSP or BSP.

The encapsulation member 180 can be disposed on the first light-emitting diode ED1 and the second light-emitting diode ED2 in each sub-pixel RSP, GSP or BSP. The encapsulation member 180 can prevent damages of the light-emitting diodes ED1 and ED2 due to external moisture and/or shocks. The encapsulation member 180 can have a multiple-layer structure. For example, the encapsulation member 180 can comprise, but is not limited to, a first encapsulation layer 181, a second encapsulation layer 182 and a third encapsulation layer 183 laminated sequentially on the light-emitting diodes ED1 and ED2.

Each of the first encapsulation layer 181, the second encapsulation layer 182 and the third encapsulation layer 183 can comprise an insulating material. The second encapsulation layer 182 can comprise a material different form a material in the first encapsulation layer 181 and the third encapsulation layer 183. For example, each of the first encapsulation layer 181 and the third encapsulation layer 183 can comprise an inorganic insulating material, and the second encapsulation layer 182 can comprise an organic insulating material. In this case, the light-emitting diodes ED1 and ED2 of the display device 100 can be more effectively prevented from damages due to moisture and/or shocks from the outside.

The first upper insulation layer 117 can be disposed on the encapsulation layer 180. The first upper insulation layer 117 can comprise an insulating material. For example, the first upper insulation layer 117 can comprise, but is not limited to, an inorganic insulating material such as silicon oxide (SiOₓ, wherein 0<x≤2) and silicon nitride (SiNₓ, wherein 0<x≤2). But embodiments of the present disclosure are not limited thereto.

The first light-blocking layer 191 can be disposed on the first upper insulation layer 117. In some embodiments, the first light-blocking layer 191 can be a metal layer. When a touch sensor is arranged on the encapsulation layer 180, the first light-blocking layer 191 can be a touch electrode or a touch bridge electrode. For example, when the first light-blocking layer 191 is the touch bridge electrode, the first light-blocking layer 191 can connect electrically plural touch electrodes disposed thereon. The first light-blocking layer 191 can be disposed to overlap with at least a portion of the bank insulation layer 116. For example, the first light-blocking layer 191 can comprise, but is not limited to, a metallic material such as titanium (Ti), aluminum (Al), silver (Ag), copper (Cu), magnesium-silver alloy (Mg:Ag), and the like. But embodiments of the present disclosure are not limited thereto, and other materials can also be used.

The second upper insulation layer 118 can be disposed on the first light-blocking layer 191. The second upper insulation layer 118 can comprise an insulating material. For example, the second upper insulation layer 118 can comprise, but is not limited to, an inorganic insulating material such as silicon oxide (SiOₓ, wherein 0<x≤2) and silicon nitride (SiNₓ, wherein 0<x≤2). But embodiments of the present disclosure are not limited thereto.

The second light-blocking layer 192 can be disposed on the second upper insulation layer 118. In some embodiment, the second light-blocking layer 192 can be a black matrix. The second light-blocking layer 192 can be arranged among the plural sub-pixels RSP, GSP and BSP to reduce color mixing of the plural sub-pixels RSP, GSP and BSP. The second light-blocking layer 192 can be arranged to overlap with a portion of the bank insulation layer 116 and/or a portion of the first light-blocking layer 191.

The planarization layer 119 can be disposed on the second light-blocking layer 192. The planarization layer 192 can eliminate the step due to the first and second light-blocking layers 191 and 192. The planarization layer 119 can comprise an insulating material. For example, the planarization layer 119 can comprise, but is not limited to, an organic insulating material.

The third light-blocking layer 193 can be disposed on the planarization layer 119. The third light-blocking layer 193 can be a metal layer. When the touch sensor is arranged on the encapsulation member 180, the third light-blocking layer 193 can be a touch electrode. When the third light-blocking layer 193 is the touch electrode, the third light-blocking layer 193 can be configured to sense external touch input using a user's finger and/or a touch pen. The third light-blocking layer 193 can be arranged to overlap with at least a portion of the bank insulation layer 116, at least a portion of the first light-blocking layer 191 and/or at least a portion of the second light-blocking layer 192. The third light-blocking layer 193 can comprise, but is not limited to, a metallic material such as titanium (Ti), aluminum (Al), silver (Ag), copper (Cu), magnesium-silver alloy (Mg:Ag), and the like.

The third upper insulation layer 195 can be disposed on the third light-blocking layer 193. The third upper insulation layer 194 can comprise an insulating material. For example, the third upper insulation layer 195 can comprise, but is not limited to, an inorganic insulating material such as silicon oxide (SiOₓ, wherein 0<x≤2) and silicon nitride (SiNₓ, wherein 0<x≤2). But embodiments of the present disclosure are not limited thereto.

The first optical member 161 or the second optical member 162 can be disposed on the third upper insulation layer 195. Each of the first optical member 161 and the second optical member 162 can be arranged to cover an edge of the plural third light-blocking layers 193.

The first optical member 161 can be disposed on the first emission area RE1, GE1 or BE1 of the first light-emitting diode ED1. The light generated by the first light-emitting diode ED1 in each sub-pixel RSP, GSP or BSP can be emitted through the first optical member 161 arranged in the first optical area RWE, GWE or BWE in the corresponding sub-pixel RSP, GSP or BSP.

The first optical member 161 can have a shape in which light in at least one direction cannot be restricted. In some embodiments, the first optical member 161 positioned within each sub-pixel RSP, GSP or BSP can have a plane shape of a bar shape extending to the first direction (X axis direction). For example, the first optical member 161 can be a semi-cylindrical lens. In this case, the first optical member 161 can focus the light in the upper and lower directions (e.g., light in the second direction (Y axis direction)) emitted from the first optical area RWE, GWE or BWE in each sub-pixel RSP, GSP or BSP toward the front direction, but may not focus the light in the left and right directions (e.g., light in the first direction (X axis direction)) toward the front direction.

For example, a content of an image provided through the first optical area RWE, GWE or BWE in each sub-pixel RSP, GSP or BSP can be shared with the user and surrounding people adjacent in the first direction (X axis direction). Accordingly, content provided by light emitted through the first optical member 161 can be provided in a first viewing angle range that is a wider than the content provided by the light emitted through the second optical member 162. For example, the content provided by the light emitted through the first optical member 161 can be provided in a wide viewing mode (Share mode).

The second optical member 162 can be arranged on the second optical area RNE, GNE or BNE of the second light-emitting diode ED2. The light generated by the second light-emitting diode ED2 in each sub-pixel RSP, GSP or BSP can be emitted through the second optical member 162 arranged in the second optical area RNE, GNE or BNE in the corresponding sub-pixel RSP, GSP or BSP. For example, the second optical member 162 positioned within each sub-pixel RSP, GSP or BSP can have a circular plane shape, but is not limited thereto. Alternatively, the second optical member 162 positioned within each sub-pixel RSP, GSP or BSP can have a polygonal plane shape.

In some embodiments, the second optical member 162 can be a hemispherical lens. In this case, the light in the upper and lower directions (e.g., light in the second direction (Y axis direction)) and the light in the left and right directions (e.g., light in the first direction (X axis direction)) emitting from the second optical area RNE, GNE or BNE in each sub-pixel RSP, GSP or BSP can be focused in the front direction.

For example, the content or image provided by the second optical area RNE, GNE or BNE in each sub-pixel RSP, GSP or BSP can be not shared with people around the user. Accordingly, the content provided by the light emitted through the second optical member 162 can be provided in a second viewing angle range that is a narrower viewing angle than the content provided by the light emitted through the first optical member 161. For example, the content provided by the light emitted through the second optical member 162 can be provided in a narrow viewing mode (Private mode).

Each of the first emission area RE1, GE1 or BE1 and the second emission area RE2, GE2 or BE2 of each pixel PX can have a plane shape of a bar shape extending to the first direction (X axis direction). The first optical member 161 in each sub-pixel can have a size or dimension larger than a size or dimension of the first emission area RE1, GE1 or BE1 in the corresponding sub-pixel RSP, GSP or BSP. Accordingly, the efficiency of the light emitted from the first emission area RE1, GE1 or BE1 in each sub-pixel RSP, GSP or BSP can be further improved.

The optical member passivation layer 170 can be disposed on the first optical member 161 or the second optical member 162 in each sub-pixel RSP, GSP or BSP. The optical member passivation layer 170 can comprise an insulating material. For example, the optical member passivation layer 170 can comprise an organic insulating material. The optical member passivation layer 170 can have a refractive index smaller than a refractive index of the first optical member 161 and a refractive index of the second optical member 162 positioned within each sub-pixel RSP, GSP or BSP. Accordingly, the light passing through the first optical member 161 and the second optical member 162 in each sub-pixel RSP, GSP or BSP can be not reflected toward the substrate 110 due to the difference in refractive index with respect to the optical member passivation layer 170 in the display device 100 in accordance with the present disclosure.

Meanwhile, the size of the second emission area RE2, GE2 or BE2 of the second light-emitting diode ED2 needs to be expanded so as to improve the lifespan of the second light-emitting diode ED2 in each sub-pixel RSP, GSP or BSP. However, there is a limit to expanding the size of second optical member 162 with a circular or polygonal planar shape in corresponding to the size of the second emission area RE2, GE2 or BE2 of the second light-emitting diode ED2. For example, when the size (e.g., the length in the first direction (X axis direction)) of one second emission area RE2, GE2 or BE2 of the second light-emitting diode ED2 is larger than 80% of the size (e.g., the length in the first direction (X axis direction)) of one second optical member 162, and only one second optical member 162 is arranged corresponding to one second emission area RE2, GE2 or BE2, the incident angle of the light emitted from one end area of the second emission area RE2, GE2 or BE2 and entering to the second optical member 162 increases. Accordingly, the light can be emitted in a wider range than the second viewing angle even if the light passes through the second optical member 162. As a result, the content or image provided by the second optical area RNE, GNE or BNE in each sub-pixel RSP, GSP or BSP can be shared with people around the user.

Accordingly, it is necessary to design the content or image provided by the second optical area RNE, GNE or BNE in each sub-pixel RSP, GSP or BSP not be shared with people around the user even if the size of one second emission area RE2, GE2 or BE2 of the second light-emitting diode ED2 increases.

With reference to FIGS. 4 and 6, a plurality of second optical members 162 can be arranged to corresponding to one second emission area RE2, GE2 or BE2 of the second light-emitting diode ED2. For example, when two second optical members 162 are arranged corresponding to one second emission area RE2, GE2 or BE2 of the second light-emitting diode ED2, one of the second optical members 162 can be arranged to overlap one edge of the second emission area RE2, GE2 or BE2, and the other of the second optical members 162 can be arranged to overlap the other edge of the second emission area RE2, GE2 or BE2. A portion of one second emission area RE2, GE2 or BE2, for example a central area, may not overlap with the second optical member 162.

In some embodiments, the central axis of the second optical member 162 and one edge of one of the first to third light-blocking layers 191, 192 and 193 can be positioned on the same straight line in the third direction (Z axis direction). For example, the central axis of the second optical member 162 and one edge of the third light-blocking layer 193, which is positioned closest to the second optical member 1620 among the first to third light-blocking layers 191, 192 and 193, can be positioned on the same straight line in the third direction (Z axis direction), but is not limited thereto. In some embodiments, the central axis of the second optical member 162 can be positioned on the same straight line in the third direction (Z axis direction) as one edge of the third light-blocking layer 193, which is closer to the second emission area RE2, GE2 or BE2 along the first direction (X axis direction) among the edges of both sides of the third light-blocking layer 193.

The first direction (X axis direction) separation distance between the plurality of the second optical members 162 arranged corresponding to one second emission area RE2, GE2 or BE2 of the second light-emitting diode ED2 needs to be adjusted so that the content or image provided by the second optical area RNE, GNE or BNE in each sub-pixel RSP, GSP or BSP is not shared with or visible to people around the user.

For example, if the first direction (X axis direction) separation distance between the plurality of the second optical member 162 becomes too wide, the incident angle of the light emitted from one end area of the second emission area RE2, GE2 or BE2 in case of contacting the outer surface of the second optical member 162 increases, and the incident angle of the light entering the inside of the second optical member 162 also increases. As a result, the content or image provided by the second optical area RNE, GNE or BNE can be shared with, or be visible to, people around the user.

The separation distance in the first direction (X axis direction) between the plurality of second optical members 162 needs to be adjusted so that the incident angle when the light emitted from one end are of the second emission area RE2, GE2 or BE2 contact the outer surface of the second optical member 162 is less than a certain angle.

For example, the separation distance in the first direction (X axis direction) between the second optical members 162 can be smaller than a length in the first direction of the second emission area RE2, GE2 or BE2. In some embodiments, the central axis of the second optical member 162 and one edge of one of the first light-blocking layers 191 can be positioned on the same straight line in the second direction (Y axis direction) that is a normal direction of the plane.

With reference to FIGS. 4-6, a plane view of the pixel PX can include a plurality of sub-pixels, including the first sub-pixel RSP, the second sub-pixel GSP and the third sub-pixel BSP, for example. Respective sub-pixels RSP, GSP and BSP can include at least one of a first optical area and a second optical area. For example, each of the second sub-pixel GSP and the third sub-pixel BSP can include two optical areas, namely a first optical area GWE and a second optical area GNE for the second sub-pixel GSP, and a first optical area BWE and a second optical area BNE for the third sub-pixel BSP, but the number of the optical areas for sub-pixels can vary in various embodiments of the present disclosure. For example, at least one first optical area RWE and at least two second optical areas RNE can be included in the first sub-pixel RSP.

In various embodiments of the present disclosure, an arrangement of the first optical area and the second optical area can vary. For example, for the second sub-pixel GSP, the first optical area GWE and the second optical area GNE can be arranged extending in the first direction (X axis direction) and be separated in the second direction (Y axis direction). Similarly, for the third sub-pixel BSP, the first optical area BWE and the second optical area BNE can be arranged extending in the first direction (X axis direction) and be separated in the second direction (Y axis direction). Also, for the first sub-pixel RSP, the first optical area RWE and the second optical areas RNE can be arranged extending in the first direction (X axis direction) and be separated in the second direction (Y axis direction).

In the context of the pixel PX, the second optical area GNE of the second sub-pixel GSP and the second optical area BNE of the third sub-pixel BSP can be arranged adjacent to each other, while the first optical area GWE of the second sub-pixel GSP and the first optical area BWE of the third sub-pixel BSP can be arranged away from each other. Accordingly, in the pixel PX, the second optical area GNE of the second sub-pixel GSP and the second optical area BNE of the third sub-pixel BSP can be arranged to be between the first optical area GWE of the second sub-pixel GSP and the first optical area BWE of the third sub-pixel BSP in a plane view. Also, the first optical area RWE of the first-sub pixel RSP can be arranged to be between the second optical areas RNE of the first sub-pixel RSP. Also, in the pixel PX, the first sub-pixel RSP can be located laterally in the first direction (X axis direction) to the second sub-pixel GSP and the third sub-pixel BSP, when the second sub-pixel GSP and the third sub-pixel BSP are arranged in the second direction (Y axis direction). In other embodiments of the present disclosure, an arrangement between a first optical area and a second optical area can vary, and an arrangement between the first, second and third sub-pixels RSP, GSP, BSP can also vary.

With reference to FIGS. 4-6, each first optical area and second optical area can include at least one optical member. For example, the first sub-pixel RSP can include the first optical area RWE that includes at least one first optical member 161 and the second optical area RNE that includes at least one second optical member 162. In the case of the first sub-pixel RSP shown in FIG. 4, provided are at least two second optical area RNE each with at least two second optical members 162. Also, the second sub-pixel GSP can include the first optical area GWE that includes at least one first optical member 161 and the second optical area GNE that includes at least one second optical member 162. In the case of the second sub-pixel GSP shown in FIG. 4, provided are at least one second optical area GNE with at least four second optical members 162. Similarly, the third sub-pixel BSP can include the first optical area BWE that includes at least one first optical member 161 and the second optical area BNE that includes at least one second optical member 162. In the case of the third sub-pixel BSP shown in FIG. 4, provided are at least one second optical area BNE with at least four second optical members 162.

With reference to FIGS. 4-6, each first optical area and second optical area can include at least one emission area. For example, the first sub-pixel RSP can include the first optical area RWE that includes at least one first emission area RE1 and the second optical area RNE that includes at least one second emission area RE2. In the case of the first sub-pixel RSP shown in FIG. 4, provided are at least two second optical area RNE each with at least one second emission area RE2. Also, the second sub-pixel GSP can include the first optical area GWE that includes at least one first emission area GE1 and the second optical area GNE that includes at least one second emission areas GE2. In the case of the second sub-pixel GSP shown in FIG. 4, provided are at least one second optical area GNE with at least two second emission areas GE2. Also, the third sub-pixel BSP can include the first optical area BWE that includes at least one first emission area BE1 and the second optical area BNE that includes at least one second emission areas BE2. In the case of the third sub-pixel BSP shown in FIG. 4, provided are at least one second optical area BNE with at least two second emission areas BE2.

With reference to FIG. 4, the two second emission areas RE2 of the first sub-pixel RSP can be arranged parallel to each other in the first direction (X axis direction) while separated in the second direction (Y axis direction). In this case, the first emission area RE1 of the first sub-pixel RSP can be interposed between the two second emission areas RE2 while being parallel to the two second emission areas RE2 in the first direction (X axis direction) while separated in the second direction (Y axis direction). Also, the two second emission areas GE2 of the second sub-pixel GSP can be arranged parallel and aligned with each other in the first direction (X axis direction) while being separated with the first emission area GE1 of the second sub-pixel GSP in the second direction (Y axis direction). Also, the two second emission areas BE2 of the third sub-pixel BSP can be arranged parallel and aligned with each other in the first direction (X axis direction) while being separated with the first emission area BE1 of the third sub-pixel BSP in the second direction (Y axis direction).

With reference to FIG. 4, in the plane view, each of the first sub-pixel RSP, the second sub-pixel GSP and the third sub-pixel BSP can be symmetric about a line that extends in the second direction (Y axis direction) located at a center of each of the first sub-pixel RSP, the second sub-pixel GSP and the third sub-pixel BSP, respectively. In addition, for the second sub-pixel GSP and the third sub-pixel BSP, the second sub-pixel GSP and the third sub-pixel BSP can be symmetric about a line that extends in the first direction (X axis direction) that extend between the second sub-pixel GSP and the third sub-pixel BSP. Also, for the first sub-pixel RSP, the first sub-pixel can be symmetric about a line that extends in the first direction (X axis direction) located at a center of the first sub-pixel RSP.

With reference to FIGS. 5 and 6, a height of the first optical member 161 can be greater than a height of the second optical member 162 with respect to an upper surface of the third upper insulation layer 195. In this case, a thickness of the optical member passivation layer 170 over the first optical member 161 can be smaller than a thickness of the optical member passivation layer 170 over the second optical member 162. In various embodiments of the present disclosure, a material of the first optical member 161 and the second optical member 162 can be the same, but such is not required, and the first optical member 161 and the second optical member 162 can respectively include different materials.

With reference to FIGS. 5 and 6, a size or a length of the first emission area can correspond a size or a length of the first optical member. For example, the size or the length of the first emission area GE1 can have the size or length of the first optical member 161 in a cross sectional view for the second sub-pixel GSP. In various embodiments of the present disclosure, the size or the length of the first emission area GE1 can be approximately the same or the same as the size or length of the first optical member 161. In this regard, opposite edges of the first optical member 161 can be aligned vertically with edges of the first, second and/or third light blocking layer 191, 192, 193. Meanwhile, a size or a length of the second emission area can be different from a size or a length of the second optical member. For example, the size or the length of the second emission area GE2 can be different from the size or length of the second optical member 162 in a cross sectional view for the second sub-pixel GSP. In various embodiments of the present disclosure, the size or the length of the second emission area GE2 can be greater than the size or length of the second optical member 162. In this regard, a middle part of the second optical member 162 can be aligned vertically with edges of the first, second and/or third light blocking layer 191, 192, 193. When a plurality of second optical members 162 are provided, adjacent second optical members 162 can be separated from each other by a gap, and a portion of the second emission area GE2 can overlap the gap between the adjacent second optical members 162.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A display device, comprising:
a substrate comprising a plurality of sub-pixels;
a light-emitting diode comprising a first light-emitting diode and a second light-emitting diode disposed in one of the plurality of sub-pixels, wherein the first light-emitting diode and the second light-emitting diode are configured to emit a same color light;
a first optical member disposed in a first emission area of the first light-emitting diode; and
a second optical member disposed in a second emission area of the second light-emitting diode,
wherein a plurality of the second optical members, including the second optical member, are arranged to overlap the second emission area.

2. The display device of claim 1, wherein the first optical member has a bar shape extending in a first direction in a plane view and the second optical member has a circular or polygonal shape in the plane view.

3. The display device of claim 2, wherein each of the first emission area and the second emission area has a bar shape extending in the first direction in the plane view.

4. The display device of claim 2, further comprising a first light-blocking layer disposed on the light-emitting diode.

5. The display device of claim 4, wherein a central axis of the second optical member and one edge of the first light-blocking layer are positioned on a same straight line in a second direction that is a normal direction to the first direction in the plane view.

6. The display device of claim 4, wherein the first light-blocking layer comprises a metal layer, or a touch electrode.

7. The display device of claim 4, further comprising an encapsulation member disposed between the light-emitting diode and the first light-blocking layer.

8. The display device of claim 7, wherein the display device further comprises a second light-blocking layer disposed on the encapsulation member.

9. The display device of clam 8, wherein the second light-blocking layer comprises a black matrix.

10. The display device of claim 8, further comprising a third light-blocking layer disposed between the encapsulation member and the second light-blocking layer.

11. The display device of claim 10, wherein the third light-blocking layer comprise a metal layer.

12. The display device of claim 4, wherein the second light-emitting diode comprises:
a lower electrode;
an emissive layer disposed on the lower electrode; and
an upper electrode disposed on the emissive layer.

13. The display device of claim 12, further comprising a bank insulation layer disposed on the lower electrode and having an opening corresponding to the second emission area.

14. The display device of claim 13, wherein at least a portion of the first light-blocking layer is arranged to overlap the bank insulation layer.

15. The display device of claim 1, wherein a separation distance in a first direction between the second optical members are smaller than a length of the second emission area in the first direction.

16. A display device, comprising:
a substrate comprising a plurality of sub-pixels; and
an emission area comprising a first emission area and at least one second emission area disposed in one of the plurality of sub-pixels,
wherein the first emission area and the second emission area are configured to emit lights of a same color,
wherein the first emission area is configured to emit the light at a first viewing angle,
wherein the second emission area is configured to emit the light at a second viewing angle narrower than the first viewing angle, and
wherein the plurality of optical members are disposed corresponding to the second emission area.

17. The display device of claim 16, wherein the emission area has a plurality of second emission areas.

18. The display device of claim 16, wherein the first emission area has a size larger than a size of the second emission area.

19. The display device of claim 16, wherein each of the first emission area and the second emission area has a bar shape extending to a first direction in a plane view.

20. A display device, comprising:
a substrate comprising a plurality of pixels, each pixel including a plurality of sub-pixels;
a first emission area and a second emission area disposed in at least one of the plurality of sub-pixels, the first emission area disposed in a first optical area and the second emission area disposed in a second optical area, each of the first and second emission areas being configured to emit a same color light;
a first optical member disposed in the first optical area and entirely overlapping the first emission area; and
a second optical member disposed in a second optical area and partially overlapping the second emission area,
wherein the first emission area and the second emission area are arranged parallel to each other in a first direction, and are separated from each other in a second direction intersecting the first direction.
